(19) United States
(12) Patent Application Publication
(10) Pub. No.: US 2013/0181276 A1
(43) Pub. Date: Jul. 18, 2013

(54) NON-SELF ALIGNED NON-VOLATILE MEMORY STRUCTURE

(71) Applicants: HSIN CHANG LIN, HSINCHU COUNTY (TW); WEN CHIEN HUANG, HSINCHU COUNTY (TW); YA-TING FAN, HSINCHU COUNTY (TW)

(72) Inventors: HSIN CHANG LIN, HSINCHU COUNTY (TW); WEN CHIEN HUANG, HSINCHU COUNTY (TW); YA-TING FAN, HSINCHU COUNTY (TW)

(73) Assignee: YIELD MICROELECTRONICS CORP., HSINCHU COUNTY (TW)

(21) Appl. No.: 13/351,319

(22) Filed: Jan. 17, 2012

(51) Int. Cl. H01L 29/788

(52) U.S. Cl. 257/316; 257/E29.3

(57) ABSTRACT

A non-self aligned non-volatile memory structure includes a semiconductor substrate; a first gate insulation layer on said semiconductor substrate; a floating gate on first gate insulation layer; two doped regions in said semiconductor substrate, which are respectively on two sides of said first gate insulation layer, and adjoining said first gate insulation layer; a second gate insulation layer on said floating gate; and a control gate on said second gate insulation layer. Width of said control gate on said floating gate is less than that of said floating gate, and width of said control gate not on said floating gate is equal to or greater than width of said floating gate. Through the two non-self aligned gates, the non-volatile memory does not need to meet the requirement of gate line-to-line alignment, thus reducing complexity and cost of manufacturing process.

### BACKGROUND OF THE INVENTION

1. Field of the Invention

The present invention relates to a memory structure, and in particular to a non-self aligned non-volatile memory structure.

2. The Prior Arts

Along with the progress and development of the electronic and information Industries, the technology applied to various electronic devices are improving rapidly. In these electronic products, memory devices are mostly used to store important data. Presently, in handsets and digital cameras, the Non-Volatile Memory (NVM), for example, a flash memory is well known and being used the most frequently.

To be more specific, the Complementary Metal Oxide Semiconductor (CMOS) manufacturing process is used extensively to produce Application Specific Integrated Circuit (ASIC). In the computer age of today, the Electrically Erasable Programmable Read Only Memory (EEPROM) is utilized widely in the electronic products, for its advantages of being able to be written and read data electrically as non-volatile memory, and the data stored therein will not be lost even after the power is off.

In general, the non-volatile memory is programmable, and that is used to store electric charges to change the gate voltage of the transistor in the memory, or it does not store electrical charges to keep the original gate voltage of the transistor in a memory unchanged. Moreover, an erasure operation is used to remove all the electrical charges stored in the non-volatile memory, so that the non-volatile memory returns to the original gate voltage of the transistor in the memory.

In the prior art, the non-volatile memory can be classified into two types of silicon structures, wherein, one is the mainstream Floating Gate structure, and the other is a silicon-oxide-nitride-oxide-silicon (SONOS) structure. According to researches conducted by various flash memory manufacturers, the Floating Gate structure has its limitations, for example, size of NOR chip has to be less than 45 nm, while size of NAND chip has to be less than 32 nm. Furthermore, in general, the gate of the non-volatile memory is composed of a control gate and a floating gate of equal width. Therefore, in the subsequent thermal process of NVM, additional three or four photo masks are required to meet the requirement of specification of gate line-to-line alignment. As such, that will increase significantly the number of process, complexity, and cost of manufacturing.

Therefore, presently, the design and manufacturing of non-volatile memory of the prior art is not quite satisfactory, and it has much room for improvements.

### SUMMARY OF THE INVENTION

In view of the problems and shortcomings of the prior art, the present invention provides a non-self aligned non-volatile memory structure, to solve the problem of the prior art.

A major objective of the present invention is to provide a non-self aligned non-volatile memory structure, that is realized through designing a control gate of reduced width on the floating gate, yet the width of the control gate not on the floating gate can be equal to or greater than the width of the floating gate, so that two gates of the non-volatile memory form into a non-self alignment, hereby reducing the area of floating gate required to protrude from the first gate insulation layer.

Another objective of the present invention is to provide a non-self aligned non-volatile memory structure, such that through the two non-self aligned gates, to solve the problem of having to achieve line-to-line alignment of gates for the non-volatile memory of the prior art, thus reducing significantly the complexity of the manufacturing process, and the number of layers of photo masks required, in achieving production cost reduction.

In order to achieve the above-mentioned objective, the present invention provide a non-self aligned non-volatile memory structure, comprising a semiconductor substrate; a first gate insulation layer; a floating gate; two doped regions; a second gate insulation layer; and a control gate. Wherein, the first gate insulation layer is located on the semiconductor substrate; the floating gate is on the first gate insulation layer; the two doped regions are in the semiconductor substrate, such that the two doped regions are provided on two sides of the first gate insulation layer, and adjoining the first gate insulation layer; the second gate insulation layer is disposed on the floating gate; and the control gate is on the second gate insulation layer, and the width of the control gate is less than that of the floating gate.

According to one embodiment of the present invention, the semiconductor substrate further includes a well shape region, so that the two doped regions are in the well shape region.

According to another embodiment of the present invention, when the semiconductor substrate or well region is of N-type semiconductor, the two doped regions are of P-type semiconductor.

According to a further embodiment of the present invention, when the semiconductor substrate or well region is of P-type semiconductor, the two doped regions are of N-type semiconductor.

Further scope of the applicability of the present invention will become apparent from the detailed description given hereinafter. However, it should be understood that the detailed description and specific examples, while indicating preferred embodiments of the present invention, are given by way of illustration only, since various changes and modifications within the spirit and scope of the present invention will become apparent to those skilled in the art from this detailed description.

### BRIEF DESCRIPTION OF THE DRAWINGS

The related drawings in connection with the detailed description of the present invention to be made later are described briefly as follows, in which:

FIG. 1 is a side view of a non-self aligned non-volatile memory structure according to an embodiment of the present invention;

FIG. 2 is a side view of a non-self aligned non-volatile memory structure according to another embodiment of the present invention;

FIG. 3 is a side view of a non-self aligned non-volatile memory structure according to an embodiment of the present invention;

FIG. 4 is a side view of a non-self aligned non-volatile memory structure according to another embodiment of the present invention;

FIG. 5 is a top view of a non-self aligned non-volatile memory structure shown in FIG. 1 according to an embodiment of the present invention; and

FIG. 6 is a top view of a non-self aligned non-volatile memory structure shown in FIG. 2 according to another embodiment of the present invention.

### DETAILED DESCRIPTION OF THE PREFERRED EMBODIMENT

The purpose, construction, features, functions and advantages of the present invention can be appreciated and understood more thoroughly through the following detailed description with reference to the attached drawings. And, in the following, various embodiments are described in explaining the technical characteristics of the present invention.

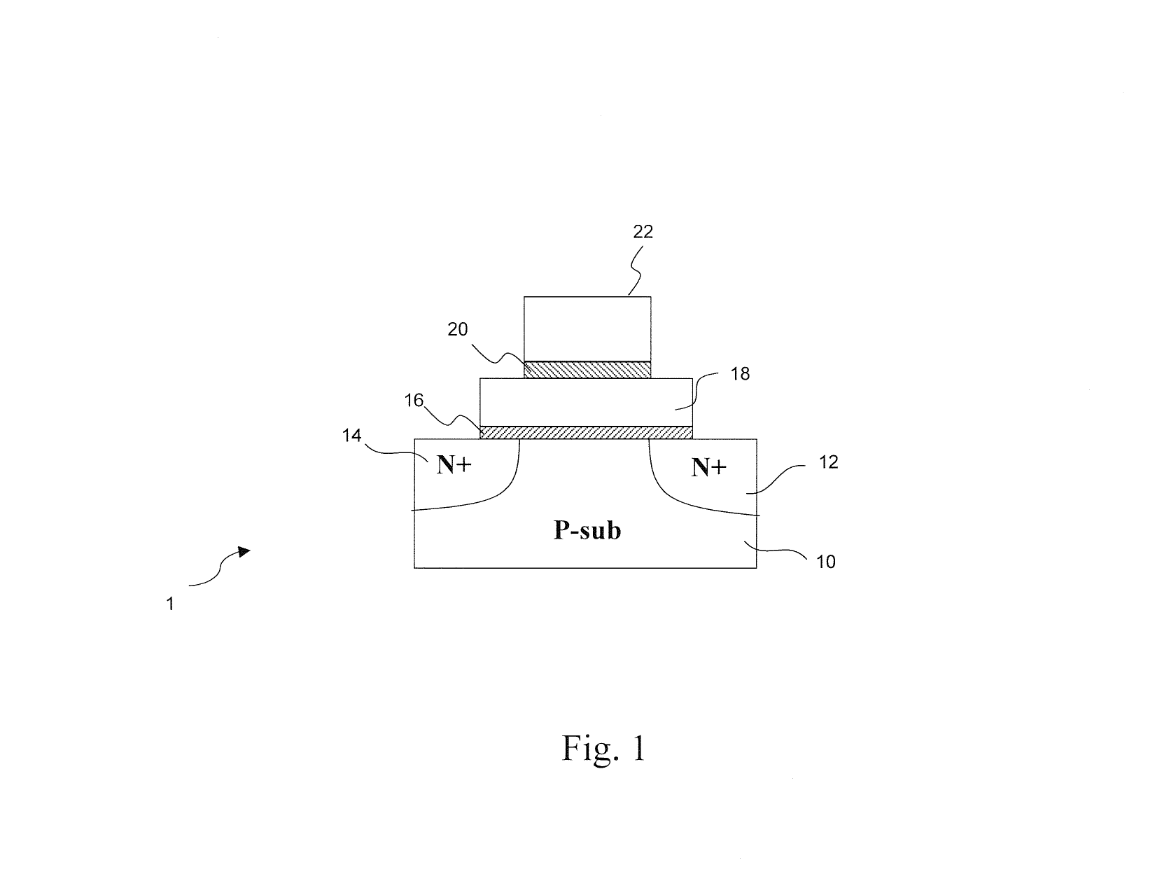

Refer to FIG. 1 for a side view of a non-self aligned non-volatile memory structure according to an embodiment of the present invention. As shown in FIG. 1, the non-self aligned non-volatile memory structure 1 of the present invention includes: a semiconductor substrate 10, a first gate insulation layer 16 on the semiconductor substrate 10; a floating gate 18 disposed on the first gate insulation layer 16; a second gate insulation layer 20 on the floating gate 18; and a control gate 22 on the second gate insulation layer 20. Wherein, the floating gate 18 and the control gate 22 can be made of poly-silicon, and the width of control gate 22 on the floating gate 18 is less than that of the floating gate 18.

Two doped regions 12 and 14 are provided in the semiconductor substrate 10, such that they are on two sides of the first gate insulation layer 16 respectively, and adjoining the first gate insulation layer 16.

In the descriptions mentioned above, the two doped regions 12 and 14 are respectively a source and a drain of the non-volatile memory structure 1.

According to one embodiment of the present invention, the first gate insulation layer 16 can be made of silicon oxide (SiO₂), and the second gate insulation layer 20 can be made of tetraethyl-ortho-silicate (TEOS), such that the thickness of the second gate insulation layer 20 is slightly greater than that of the first gate insulation layer 16.

More specifically, as shown in FIG. 1, when the semiconductor substrate is a P-type semiconductor substrate (P-substrate) 10, the two doped regions 12 and 14 are N-type doped regions. However, the present invention is not limited herein.

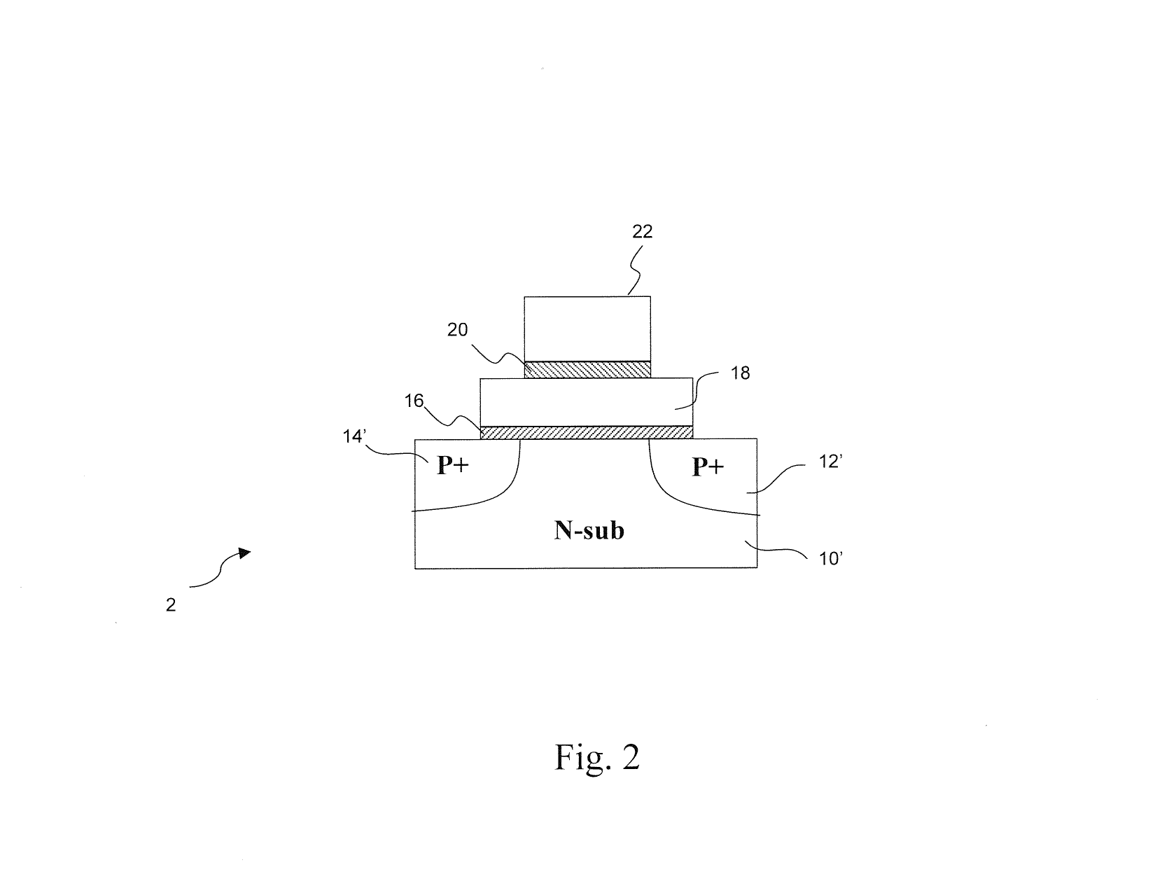

Refer to FIG. 2 for a side view of a non-self aligned non-volatile memory structure according to another embodiment of the present invention. As shown in FIG. 2, the semiconductor substrate of the non-self aligned non-volatile memory structure 2 can also be an N-type semiconductor substrate (N-substrate) 10′, and in this condition, the two doped regions 12 and 14 are P-type doped regions.

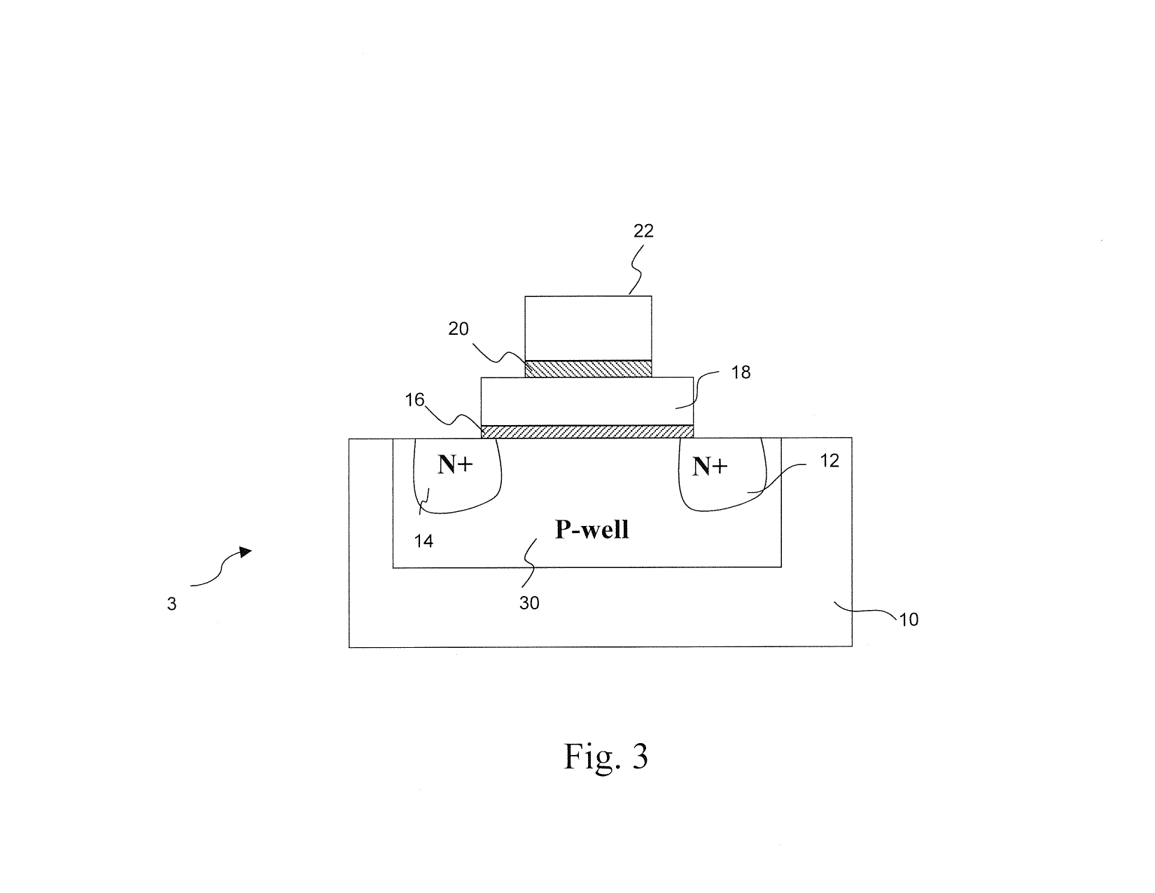

Refer to FIG. 3 for a side view of a non-self aligned non-volatile memory structure according to an embodiment of the present invention. As shown in FIG. 3, the semiconductor substrate 10 may further include a well region 30, so that the two doped regions 12 and 14 are disposed in the well regions 30.

In this embodiment, when the well region 30 of the non-self aligned non-volatile memory structure 3 is a P-type well region (P-well), the two doped regions 12 and 14 are N-type doped regions. However, the present invention is not limited to this.

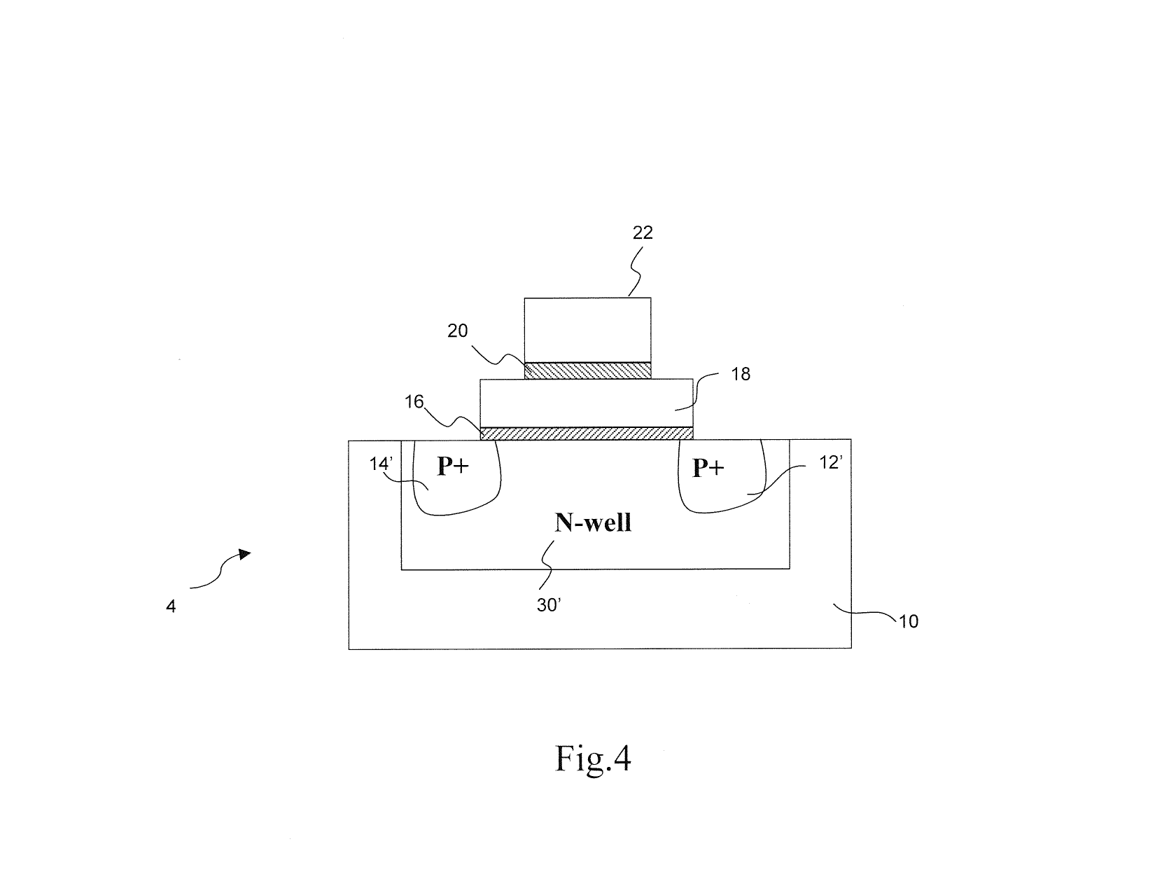

Refer to FIG. 4 for a side view of a non-self aligned non-volatile memory structure according to another embodiment of the present invention. As shown in FIG. 4, the well region of the non-self aligned non-volatile memory structure 4 can also be an N-type well region (N-well) 30′, and in this condition, the two doped regions 12′ and 14′ are P-type doped regions.

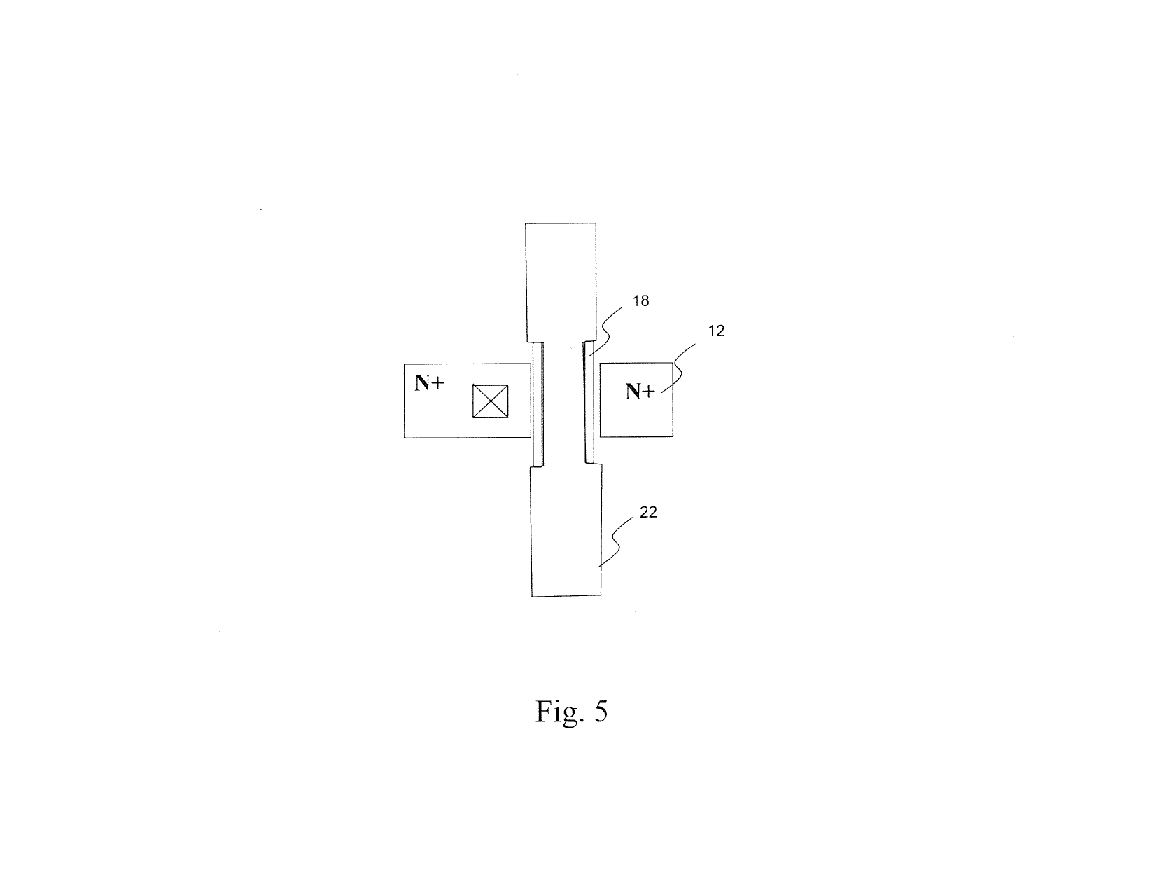

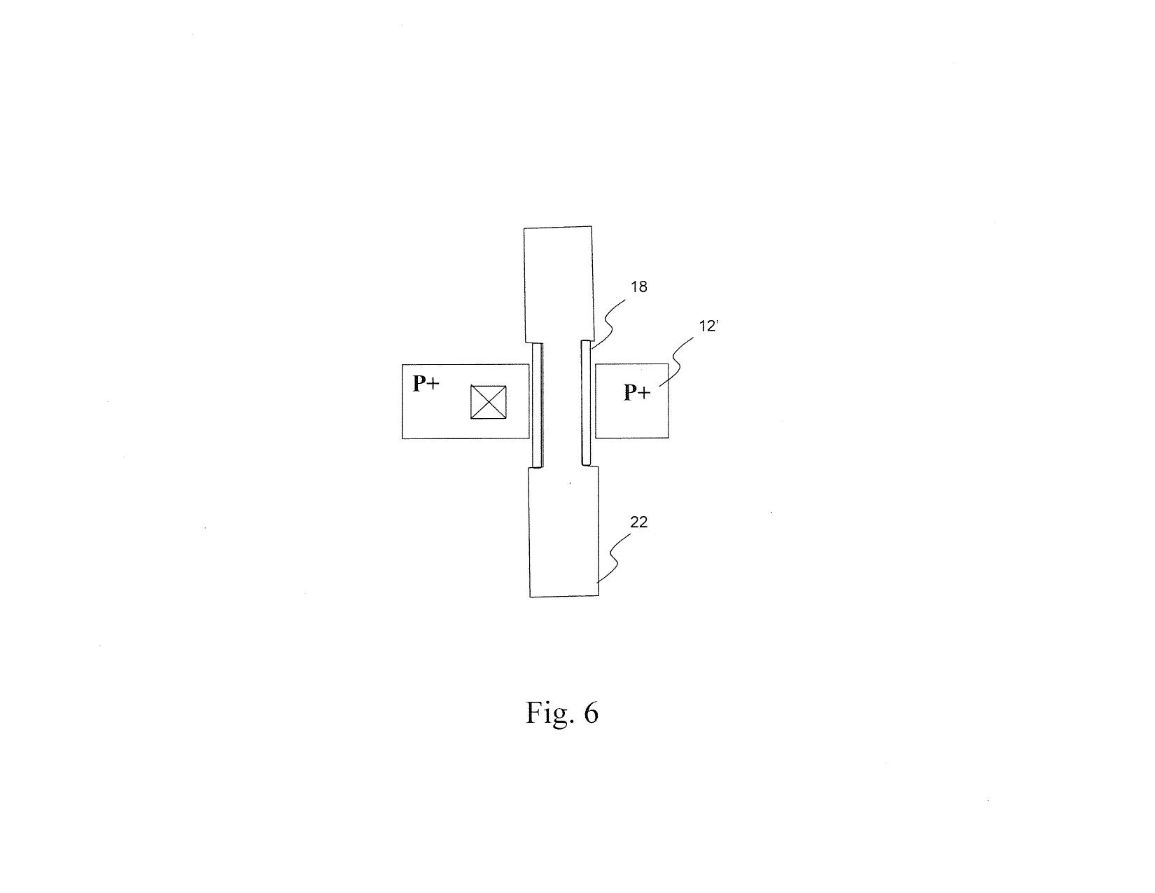

Finally, refer to FIGS. 5 and 6 for top views of a non-self aligned non-volatile memory structure shown in FIGS. 1 and 2 respectively according to the present invention. As shown in FIGS. 5 and 6, it can be seen that, the control gate 22 is on the floating gate 18, with its width less than that of the floating gate 18. Yet, for the control gate 22 not on the floating gate 18, its width may equal to or greater that of the floating gate 18.

Summing up above, the present invention discloses a non-self aligned non-volatile memory structure, that makes use of a control gate with its width slightly less than the floating gate, so that the two gates of the non-volatile memory form into a non-self alignment. As such, through the two non-self aligned gates to solve the problem of the prior art that the non-volatile memory must achieve line-to-line alignment of gates, thus reducing significantly the complexity of manufacturing processes and the number of photo mask layers required, in realizing reduction of production cost.

The above detailed description of the preferred embodiment is intended to describe more clearly the characteristics and spirit of the present invention. However, the preferred embodiments disclosed above are not intended to be any restrictions to the scope of the present invention. Conversely, its purpose is to include the various changes and equivalent arrangements which are within the scope of the appended claims.

What is claimed is:

1. A non-self aligned non-volatile memory structure, comprising:
a semiconductor substrate;
a first gate insulation layer, provided on said semiconductor substrate;
a floating gate, provided on said first gate insulation layer;
two doped regions, provided in said semiconductor substrate, said two doped regions are on two sides of said first gate insulation layer respectively, and adjoining said first gate insulation layer;
a second gate insulation layer, provided on said floating gate; and
a control gate, provided on said second gate insulation layer, and width of said control gate on said floating gate is less than that of said floating gate.

2. The non-self aligned non-volatile memory structure as claimed in claim 1, wherein width of said control gate not on said floating gate is equal to or greater than that of said floating gate.

3. The non-self aligned non-volatile memory structure as claimed in claim 1, wherein said semiconductor substrate is a first type semiconductor substrate, and said two doped regions are second type doped regions.

4. The non-self aligned non-volatile memory structure as claimed in claim 3, wherein when said first type semiconductor substrate is an N-type semiconductor substrate, said second type doped regions are P-type doped regions.

5. The non-self aligned non-volatile memory structure as claimed in claim 3, wherein when said first type semiconductor substrate is a P-type semiconductor substrate, said second type doped regions are N-type doped regions.

6. The non-self aligned non-volatile memory structure as claimed in claim 1, wherein said first gate insulation layer is made of silicon dioxide (SiO₂).

7. The non-self aligned non-volatile memory structure as claimed in claim 1, wherein said second gate insulation layer is made of tetraethyl-ortho-silicate (TEOS).

8. The non-self aligned non-volatile memory structure as claimed in claim 1, wherein said floating gate and said control gate are made of poly-silicon.

9. The non-self aligned non-volatile memory structure as claimed in claim 1, wherein thickness of said second gate insulation layer is greater than that of said first gate insulation layer.

10. The non-self aligned non-volatile memory structure as claimed in claim 1, wherein said two doped regions are a source and a drain respectively of said non-self aligned non-volatile memory structure.

11. The non-self aligned non-volatile memory structure as claimed in claim 1, wherein said semiconductor substrate is further provided with a well region, and said two doped regions are disposed in said well region.

12. The non-self aligned non-volatile memory structure as claimed in claim 11, wherein said well region is a first-type well region, said two doped regions are said second type doped regions.

13. The non-self aligned non-volatile memory structure as claimed in claim 12, wherein when said first type well region is an N-type well region, said second type doped regions are said P-type doped regions.

14. The non-self aligned non-volatile memory structure as claimed in claim 12, wherein when said first type well region is a P-type well region, said second type doped regions are N-type doped regions.
